(19) United States
(12) Patent Application Publication
(10) Pub. No.: US 2026/0181867 A1
(43) Pub. Date: Jun. 25, 2026

(54) SEMICONDUCTOR DEVICE AND METHOD OF FORMING THE SAME

(71) Applicant: Fujian Jinhua Integrated Circuit Co., Ltd., Quanzhou City (CN)

(72) Inventor: Li-Wei Feng, Quanzhou City (CN)

(73) Assignee: Fujian Jinhua Integrated Circuit Co., Ltd., Quanzhou City (CN)

(21) Appl. No.: 19/422,362

(22) Filed: Dec. 16, 2025

(30) Foreign Application Priority Data
Dec. 20, 2024 (CN) 202411896359.1

(51) Int. Cl. H10B 12/00; H10D 1/68; H10D 64/27

(52) U.S. Cl. CPC H10B 12/315; H10B 12/02; H10B 12/34; H10B 12/488; H10D 1/716; H10D 64/513

(57) ABSTRACT

The present invention provides a semiconductor device and a method of forming the same, which is widely used in a semiconductor technique. In the present invention, the semiconductor device includes a first insulating structure having a multilayer structure, and a plurality of insulating layer disposed therein includes a seam and/or a recess gap, so as to enhance the function and reliability of the semiconductor device.

### CROSS REFERENCE TO RELATED APPLICATION

This application claims the benefit of Chinese Patent Application No. 202411896359.1 filed on Dec. 20, 2024, which is incorporated herein by reference.

### BACKGROUND OF THE INVENTION

### 1. Field of the Invention

The present invention generally relates to a semiconductor technique, and more particularly, to a semiconductor device and a method of forming the same.

### 2. Description of the Prior Art

A dynamic random access memory (DRAM) device is one kind of volatile memory that has an array area being consisted of a plurality of memory cells, and a peripheral area being consisted of control circuits. Each memory cell includes a transistor and a capacitor serially connected to the transistor, with the transistor controlling the release or save of charge in the capacitor for data storage. The control circuit identifies each memory cell through a word line (WL) and a bit line (BL) which intersects the array area and is electrically connected to each memory cell, so as to control the data access of each memory cell. However, due to the fabricating limitations, there are still many defects in the conventional dynamic random access memory, which need to be further improved for increasing device performance and reliability of related memory components.

### SUMMARY OF THE INVENTION

An object of the present invention is to provide a semiconductor device and a method of forming the same, for enhancing the function and the reliability of the semiconductor device.

In the first aspect, in order to improve the technical issues above, the present invention provides a semiconductor device at least including a substrate, a first insulating structure, and a first contact structure. The first insulating structure is disposed on the substrate, and includes a first insulating layer and a second insulating layer, wherein the first insulating layer and the second insulating layer include a first seam and a second seam, respectively. The first contact structure is disposed adjacent to the first insulating structure.

Optionally, the first insulating structure includes a recess gap between the first insulating layer and the second insulating layer thereof, and a maximum width of the recess gap in a horizontal direction is greater than a maximum width of the first seam within the first insulating layer in the horizontal direction.

Optionally, the recess gap directly contacts the first seam and/or the second seam.

Optionally, a top surface of the recess gap is higher than a top surface of the first contact structure.

Optionally, the semiconductor device further includes a word line disposed within the substrate, being overlaid by the first insulating structure.

Optionally, the first insulating structure further includes a third insulating layer disposed between the first insulating layer and the second insulating layer.

Optionally, the first insulating structure includes a gap between the third insulating layer and the first insulating layer, and the gap contacts the first seam.

Optionally, the first seam within the first insulating layer is overlaid by the second seam within the second insulating layer in vertical direction.

Optionally, the first seam within the first insulating layer is communicated with the second seam within the second insulating layer.

Optionally, the third insulating layer further disposed on two outer sidewalls of the first insulating layer.

Optionally, the second insulating layer extends to cover a partial sidewall of the third insulating layer disposed on the two outer sidewall of the first insulating layer.

Optionally, the semiconductor device further includes a second contact structure disposed on the first contact structure. The second contact structure extends in a horizontal direction to cover a partial surface of the first insulating structure.

Optionally, the semiconductor device further includes a second insulating structure disposed adjacent to the second contact structure, and the second insulating structure directly contacts the recess gap of the first insulating structure.

Optionally, the second insulating structure directly contacts the second seam within the second insulating layer of the first insulating structure.

In the second aspect, under the same inventing concept, the present invention also provides a method of forming a semiconductor device including the following steps. A substrate is provided. A first insulating structure is formed on the substrate, and includes a first insulating layer and a second insulating layer. The first insulating layer and the second insulating layer of the first insulating structure include a first seam and a second seam, respectively. A first contact structure is formed adjacent the first insulating structure.

Optionally, forming the first insulating structure includes the following steps. A sacrificial layer is formed on the substrate, the sacrificial layer including a through hole. A first insulating material layer is formed to fill in the through hole, wherein the first seam is formed within the first insulating material layer. An etching back process is formed to partially remove the first insulating material layer, to form a recess on an upper portion thereof, wherein a bottom portion of the recess contacts the first seam. The second insulating layer is formed to fill in the recess and extended to partially cover two sidewalls of the first insulating layer, wherein the second seam is formed within the second insulating layer.

Optionally, the first insulating structure includes a recess gap between the first insulating layer and the second insulating layer thereof, and a maximum width of the recess gap in a horizontal direction is greater than a maximum width of the first seam within the first insulating layer in the horizontal direction.

Optionally, before forming the second insulating layer, a third insulating layer is further formed between the first insulating layer and the second insulating layer, and the third insulating layer extends to cover on two outer sidewalls of the first insulating layer.

Optionally, the first insulating structure includes a gap between the third insulating layer and the first insulating layer, and the gap contacts the first seam.

According to the present invention, a first insulating structure at least includes a first insulating layer and a second insulating layer, wherein the first insulating layer and the second insulating layer of the first insulating structure includes a seam disposed therein, for example a first seam disposed within the first insulating layer and a second seam disposed within the second insulating layer. Also, the first insulating structure includes a recess gap between the first insulating layer and the second insulating layer thereof. That is, through arranging the first insulating structure having a multilayer structure, and arranging insulating layers disposed therein having a seam and/or a recess gap, the semiconductor device is allowable to obtain the first insulating structures having a novel structure, so as gain better performances and reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic diagram illustrating a semiconductor device according to a first embodiment of the present invention.

FIG. 2 is a schematic diagram illustrating a semiconductor device according to a second embodiment of the present invention.

FIG. 3 to FIG. 14 are schematic diagrams illustrating a method of forming a semiconductor device according to a preferred embodiment of the present invention, wherein:

FIG. 3 is a schematic top view of the semiconductor structure after forming word lines and bit lines;

FIG. 4 is a schematic cross-sectional view taken along a cross line A-A′ in FIG. 3;

FIG. 5 is a schematic cross-sectional view of the semiconductor structure after forming a sacrificial layer;

FIG. 6 is a schematic cross-sectional view of the semiconductor structure after forming through holes;

FIG. 7 is a schematic cross-sectional view of the semiconductor structure after forming first insulating material layer;

FIG. 8 is a schematic cross-sectional view of the semiconductor structure after forming recesses;

FIG. 9 is a schematic cross-sectional view of the semiconductor structure after removing sacrificial layer;

FIG. 10 is a schematic cross-sectional view of the semiconductor structure after forming a third insulating layer;

FIG. 11 is a schematic cross-sectional view of the semiconductor structure after forming contact openings;

FIG. 12 is a schematic cross-sectional view of the semiconductor structure after forming a first contact material layer;

FIG. 13 is a schematic cross-sectional view of the semiconductor structure after forming first contact structures; and

FIG. 14 is a schematic cross-sectional view of the semiconductor structure after forming a second insulating layer.

### DETAILED DESCRIPTION

To provide a better understanding of the purpose, the technical features and the advantages of the present invention, preferred embodiments will be described in detail with accompanying drawings hereinafter. It is noted that although exemplifying some embodiments in the drawings of the present invention, the present invention may also be achieve in various forms and should not be limited by the embodiments set forth herein. These embodiments are provided for those skilled in the art to fully realize and to implement the technical features of the present invention.

In the following paragraphs, the present invention is described in further detail with reference to the accompanying drawings. The advantages and features of the invention will become clearer based on the following description and the claims. It is also noted that the drawings are presented in a highly simplified form and with imprecise proportions, and which are only used for facilitating and clearly illustrating the embodiments of the present invention. Please understand that, spatially relative terms, such as “beneath,” “below,” “lower,” “over,” “above,” “upper” and the like, may be used herein for describing feature's relationship in the broadest manner, so that, which refers to the target either being disposed directly “on” a subject without any intervening features or layers therebetween, or being disposed on a subject with other intervening features or layers therebetween.

For better understanding, a horizontal direction and a vertical direction are defined in the following paragraphs, the horizontal direction refers to the direction being parallel to a surface of a substrate 100, and the vertical direction refers to the direction being perpendicular to the surface of the substrate 100.

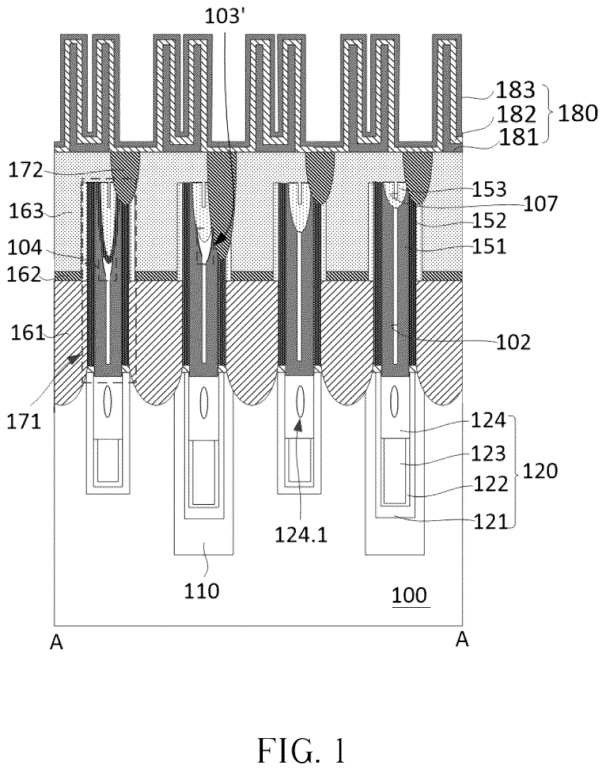

Please refer to FIG. 1, which schematically illustrates a cross-sectional view of a semiconductor device according to the first embodiment of the present invention. The semiconductor device of the present invention can be used to fabricate a dynamic random access memory (DRAM), and also be applied to other types of memory devices without being contrary the spirit of the present invention.

As shown in FIG. 1, the semiconductor device includes the substrate 100, a plurality of word lines 120, a plurality of first contact structures 161, a silicide layer 162, a plurality of second contact structures 163, a plurality of first insulating structures 171, a plurality of second insulating structures 172, and a plurality of capacitors 180. The substrate 100 may include any suitable material known in the art, for example being a silicon substrate, a silicon-containing substrate (SiC or SiGe), a silicon-on-insulator (SOI) substrate, or a substrate formed of any other suitable material, but not limited thereto. The substrate 100 further includes a plurality of trench isolations 110 disposed therein, to define a plurality of active areas (not shown in the drawings) extending in a same direction, in the substrate 100. In one embodiment, the trench isolations 110 may each includes a long-striped shaped and arranges in sequence along the horizontal direction. The trench isolations 110 may include a monolayer or a multilayer of dielectric materials, for example including but not limited to, silicon oxide, silicon nitride, silicon oxynitride, silicon carbonitride, low dielectric constant dielectric materials like fluorosilicone glass, silicon carbide oxide, spin-on silicon glass, porous low dielectric constant dielectric materials, organic polymer dielectric materials, or a combination thereof. The word lines 120 are disposed within the trench isolations 110, and which can also include a long-striped shape. Also, the word lines 120 are separately arranged in the horizontal direction and each extends in the vertical direction, to further include a gate dielectric layer 121 (for example including a high dielectric constant dielectric material), a work function metal layer 122 (for example including a material like titanium nitride), a conductive layer 123 (for example including a material like tungsten) and an insulating cover layer 124 (for example including a material like oxide or nitride), but not limited thereto. The insulating cover layer 124 of at least one of the word lines 120 includes a seam 124.1 disposed therein, but not limited thereto.

The first insulating structures 171 are separately arranged in the horizontal direction, on the substrate 100, and each includes a long-stripe shape in the vertical direction. Each of the first insulating structures 171 at least includes a first insulating layer 151 and a second insulating layer 153. In one embodiment, the first insulating layer 151 and the second insulating layer 153 are stacked from bottom to top in the vertical direction. Precisely speaking, the second insulating layer 153 is disposed on a top portion of the first insulating layer 151, being partially embedded in the first insulating layer 151 and further covering an upper portion of two outer sidewalls of the first insulating layer 151 of each of the first insulating structures 171. That is, a top surface of the second insulating layer 153 in each of the first insulating structures 171 is flush with top surfaces of the first insulating layers 151 at two sides thereof. Also, the first insulating layer 151 and the second insulating layer 153 of at least one of the first insulating structures 171 includes a seam disposed therein, for example, a first seam 102 is disposed within the first insulating layer 151 and a second seam 107 is disposed within the second insulating layer 153.

It is noted that, in the present embodiment, the first seam 102 within the first insulating layer 151 has a relative longer length extending in the vertical direction, and the second seam 107 within the second insulating layer 153 is not limited thereto. In other words, a bottom portion of the second seam 107 may include a height either being the same as or being higher than that of the bottom portion of the second insulating layer 153, in the vertical direction. In addition, a length of the second insulating layer 153 within the first insulating layer 151 in the vertical direction may vary with processes, so that the bottom portion of a part of the second insulating layer 153 disposed within the first insulating layer 151 will direct contact the first seam 102 within the first insulating layer 151, and the bottom portion of another part of the second insulating layer 153 disposed within the first insulating layer 151 will not contact the first seam 102 within the first insulating layer 151. Accordingly, there is a recess gap 103′ defined between the bottom portion of the another part of the second insulating layer 153 and the first insulating layer 151. Preferably, a maximum width of the recess gap 103′ between the first insulating layer 151 and the second insulating layer 153 in the horizontal direction may be larger than a maximum width of the first seam 102 within the first insulating layer 151, and a top surface of the recess gap 103′ between the first insulating layer 151 and the second insulating layer 153 is higher than a top surface of each first contact structures 161. Optionally, a bottom surface of the recess gap 103′ between the first insulating layer 151 and the second insulating layer 153 may be higher, lower, or the same as the top surface of the each first contact structures 161. Moreover, the first seam 102 within the first insulating layer 151 may be overlaid by the second seam 107 within the second insulating layer 153 of the same one of the first insulating structures 171, and also, the first seam 102 within the first insulating layer 151 and/or the second seam 107 within the second insulating layer 153 is overlaid by the seam 124.1 within the insulating cover layer 124 of a corresponding one of the word lines 120, but not limited thereto.

In one embodiment, at least a portion of the first insulating structures 171 further includes a third insulating layer 152 disposed therein. Precisely speaking, the third insulating layer 152 may be disposed on two outer sidewalls of the first insulating layer 151 of each first insulating structure 171, or the third insulating layer 152 may also be disposed between the first insulating layer 151 and the second insulating layer 153 of each first insulating structure 171 and further extends to cover the two outer sidewalls of the first insulating layer 151. With these arrangements, the portion of the second insulating layer 153 overlaying the two outer sidewalls of the first insulating layer 151 is actually on the two outer sidewalls of the third insulating layer 152. Also, a gap 104 may be defined between the third insulating layer 152 and the first insulating layer 151 of the same first insulating structure 171, and the gap 104 directly contacts the first seam 102 within the first insulating layer 151. In other embodiments, the third insulating layer 152 may also be directly in contact with the first seam 102 within the first insulating layer 151 of the same first insulating structure 171, instead of generating a gap (not shown in the drawings) therebetween. Likewise, a maximum width of the gap 104 between the third insulating layer 152 and the first insulating layer 151 in the horizontal direction may also be larger than the maximum width of the first seam 102 within the first insulating layer 151, and a top surface of the gap 104 between the third insulating layer 152 and the first insulating layer 151 can also be higher than the top surface of each first contact structure 161. Optionally, a bottom surface of the gap 104 between the third insulating layer 152 and the first insulating layer 151 may be higher, lower, or the same as the top surface of the each first contact structures 161.

It is noted that, the first insulating layer 151, the second insulating layer 153 and the third insulating layer 152 all include an insulating material, such as silicon oxide or silicon nitride, and the materials of the first insulating layer 151, the second insulating layer 153 and the third insulating layer 152 may be the same as or different from each other, and preferably including different insulating materials.

The first contact structures 161 are separately arranged in the horizontal direction, between adjacent ones of the first insulating structures 171, with the top surface of each first contact structure 161 being lower than a top surface of any one of the first insulating structures 171 disposed at two sides thereof. The silicide layer 162 is disposed on the top surface of each first contact structure 161, and the second contact structures 163 are disposed on the first contact structures 161, respectively, with each second contact structure 163 extending in the horizontal direction to partially cover the top surface of a corresponding one of the first insulating structures 171. The second insulating structures 172 are respectively disposed between adjacent ones of the second contact structures 163, crossing through the second contact structures 163 to directly contact the first insulating structure 171. In the present embodiment, a length of each second insulating structure 172 in the vertical direction may vary with processes, so that a part of the second insulating structures 172 will cross through the corresponding first insulating structures 171 in the vertical direction, to directly contact the recess gap 103′ within the corresponding first insulating structures 171, with the part of the second insulating structures 172 directly contacting the recess gap 103′ between the first insulating layers 151 and the second insulating layers 153 in the corresponding first insulating structures 171, as shown in FIG. 1. Alternately, another part of the second insulating structures 172 may also contact the gap 104 between the third insulating layer 152 and the first insulating layer 151 in the corresponding first insulating structures 171, or directly contact the second seam 107 within the second insulating layer 153 in the corresponding first insulating structures 171, but not limited thereto.

In one embodiment, the first contact structures 161 may include but not limited to crystalline silicon, polysilicon, amorphous silicon, doped silicon, silicon germanium or other suitable silicon-containing semiconductor materials. For example, the first contact structures 161 may include silicon phosphorus. The second contact structures 163 may include a monolayer structure or a multilayer structure, including a conductive battier material like titanium and/or titanium nitride, tantalum and/or tantalum nitride, and preferably for titanium nitride, or including a metal material like tungsten, copper, aluminum, titanium, tantalum, or a nitrides, silicide, alloy, and/or a composite of the aforementioned materials, and preferably for tungsten. The second insulating structures 172 may include an insulating material, such as silicon nitride or silicon oxide, but not limited thereto.

Furthermore, the capacitors 180 are disposed on the second contact structures 163, respectively. Precisely speaking, each capacitor 180 may include a lower electrode 181, a capacitor dielectric layer 182 and an upper electrode 183, with the lower electrode 181 being disposed on the corresponding second contact structure 163, with the upper electrode 183 being disposed on the lower electrode 181, and with the capacitor dielectric layer 182 being disposed between the upper electrode 183 and the lower electrode 181.

It could be easily understood by those of ordinary skill in the art that the semiconductor device according to the present invention may have alternative forms not limited to the above, for meeting practical requirements of products. Hereinafter, other embodiments or variations of the semiconductor device and the forming method thereof according to the present invention will be further described. For simplification, the following descriptions are mainly focused on the differences between embodiments, and will not repeat the similarities. In addition, the same components in various embodiments of the present invention are labeled with the same reference numerals, so as to facilitate mutual comparison among various embodiments.

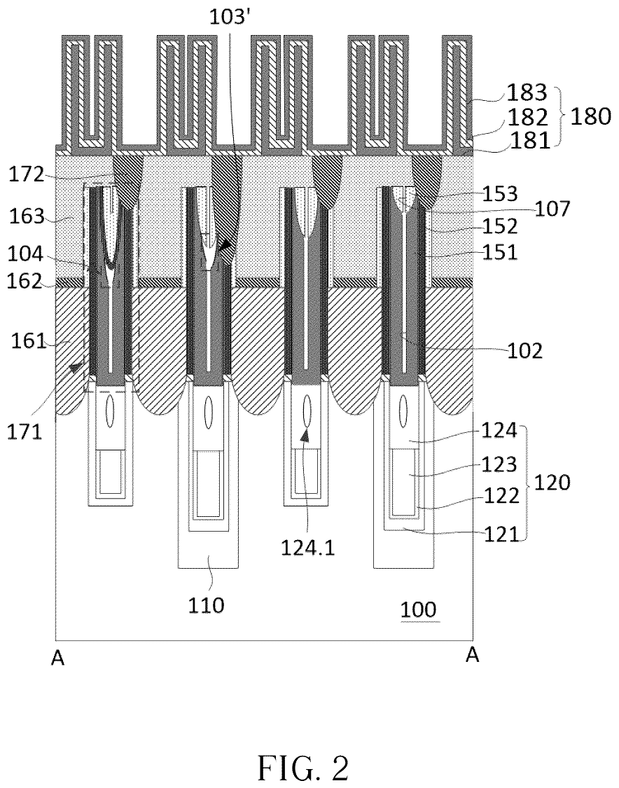

Please refer to FIG. 2, which schematically illustrates a cross-sectional view of a semiconductor device according to the second embodiment of the present invention. The structure of the semiconductor device in the present embodiment is basically the same as that of the semiconductor device in the first embodiment, for example also including the word lines 120, the first contact structures 161, the silicide layer 162, the second contact structures 163, the first insulating structures 171 (with at least one first insulating structure 171 including the first insulating layer 151 and the second insulating layer 153, with at least one first insulating structure 171 including the first insulating layer 151, the second insulating layer 153 and the third insulating layer 152, and with the first insulating layer 151 and the second insulating layer 153 respectively including the seam 102, 107 disposed therein), the second insulating structures 172 and the capacitors 180, and other similarities will not be described again. The main difference between the semiconductor device in present embodiment and the semiconductor device in the first embodiment is that the first seam 102 within the first insulating layer 151 is communicated with the second seam 107 within the second insulating layer 153 of the at least one first insulating structure 171, and/or the first seam 102 within the first insulating layer 151 of the at least one first insulating structure 171 is communicated with the recess gap 103′ between the first insulating layer 151 and the second insulating layer 153, with the first seam 102, the recess gap 103′ and the second seam 107 of the first insulating structure 171 being communicated with each other, but not limited thereto.

Under the same inventing concept, the present invention also provides a method of forming a semiconductor device at least including the following steps. In a step S100, a substrate 100 is provided. In a step S200, a plurality of first insulating structures 171 is separately formed on the substrate 100, and each of the plurality of first insulating structures 171 includes a first insulating layer 151 and a second insulating layer 153, with the first insulating layer 151 and the second insulating layer 153 of at least one of the plurality of first insulating structures 171 including a first seam 102 and a second seam 107, respectively. In a step S300, a plurality of first contact structures 161 is formed, with each first contact structure 161 being between adjacent ones of the plurality of first insulating structures 171.

To enable those skilled in the art to easily understand the semiconductor device of the present invention, the forming method of the semiconductor device of the present invention will be further described below.

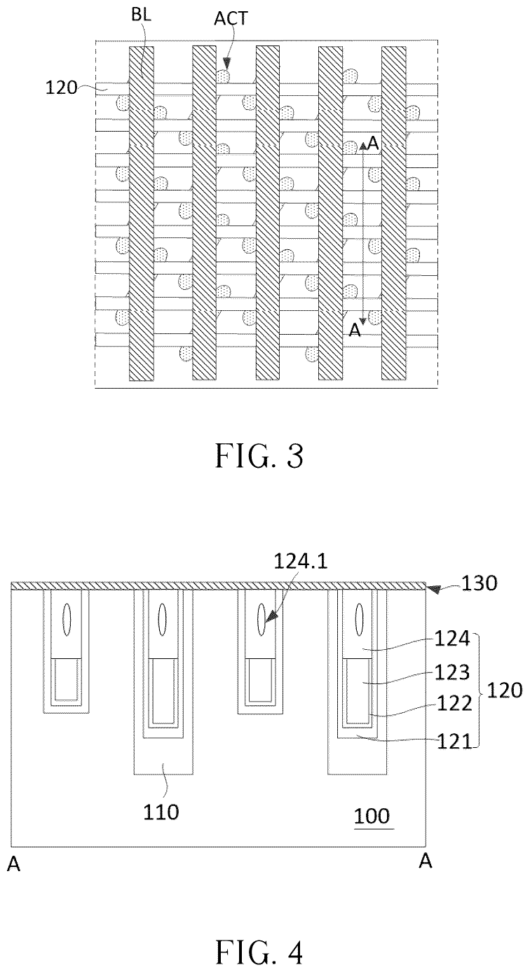

Please refer to FIGS. 3 to 14, which are schematic diagrams of the forming method of the semiconductor device in a preferred embodiment of the present invention, where FIG. 3 schematically illustrates a top view of a semiconductor device for clearly defining the relationship between specific components and/or devices in the present invention, and FIGS. 4-14 schematically illustrate a cross-sectional view tacked along a cross-line A-A′ in FIG. 3 during different forming process.

As shown in FIG. 3, the semiconductor device of the present embodiment includes a plurality of word lines 120, and a plurality of bit lines (BL) being intersected with thereto, and a plurality of active areas (ACT) disposed within the substrate 100. Since the cross-line A-A′ is set between two adjacent ones of the bit lines, in the same extending direction of that of any one of the bit lines, the structure of the bit lines is not illustrated in the cross-sectional views shown in FIGS. 4-14.

As shown in FIG. 4, the step S100 is carried out by firstly providing the substrate 100 (for example including a silicon substrate), followed by forming a plurality of trench isolations 110 in the substrate 100 and forming the word lines 120 in the trench isolations 120. In one embodiment, the fabricating process of the trench isolations 110 and the word lines 120 may include the following steps. At least one etching process such as a dry etching process or a wet etching process is performed, to form a plurality of trenches within the substrate 100, with the trenches separately arranged in sequence in the horizontal direction, and then, at least one deposition process such as a physical vapor deposition process, a chemical vapor deposition process or an atomic layer deposition process is performed, to form an insulating material such as silicon oxide or silicon nitride filled in the trenches, thereby forming the trench isolations 110. Accordingly, through the trench isolations 110 are formed, the active areas (ACTs) are defined within the substrate 100. Following these, a deposition process is performed to form a gate dielectric layer 121 (for example including a high-k dielectric material), a work function metal layer 122 (for example including titanium nitride), a conductive layer 123 (for example including tungsten) and an insulating cover layer 124 (for example including oxide or nitride) in sequence, within the corresponding trench isolations 110, with the insulating cover layer 124 having a seam 124.1 disposed therein, but not limited thereto. It is noted that, the seam 124.1 is formed within the insulating cover layer 124 of each word line 120, or the insulating cover layer 124 of a part of the word lines 120, but not limited thereto.

Next, an isolating layer 130 is formed on a surface of the substrate 100. In one embodiment, the isolating layer 130 may include a monolayer structure (as shown in FIG. 2) including a silicon oxide layer or a silicon nitride layer, or a multilayer structure (not shown in the drawings) including an oxide-nitride-oxide (ONO) structure, but not limited thereto.

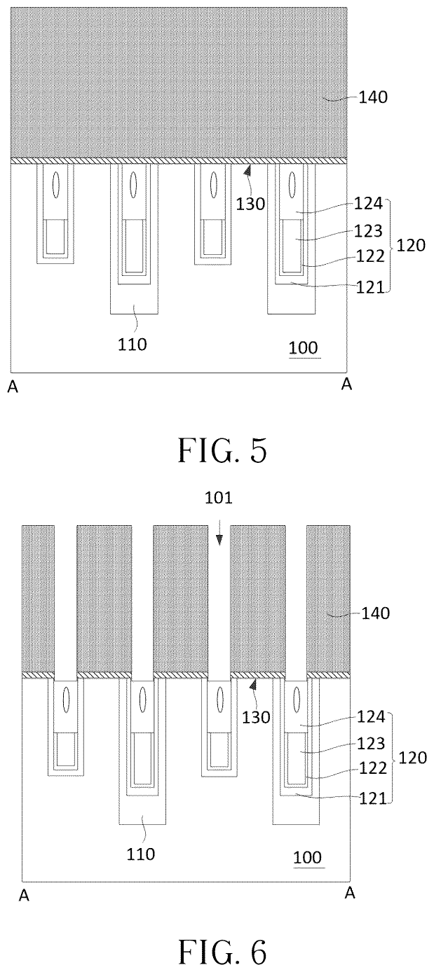

As shown in FIG. 5, at least one deposition process such as a physical vapor deposition process, a chemical vapor deposition process or an atomic layer deposition process is performed, to form a sacrificial layer 140 with a certain thickness on the isolating layer 130, over the substrate 100. In one embodiment, the sacrificial layer 140 may include a monolayer or a multilayer oxide material, like silicon oxide, boro-phospho-silicate-glass (BPSG) or other sacrificial materials, but not limited thereto.

As shown in FIG. 6, an etching process such as a dry etching process is performed, to form a plurality of through holes 101 in the sacrificial layer 140, with the through holes 101 separately arranged in sequence in the horizontal direction. In one embodiment, a number of the through holes 101 may be the same as a number of the word lines 120. It is noted that each through hole 101 of the present embodiment penetrates through the sacrificial layer 140, as well as the isolating layer 130 underneath, and partially penetrates the insulating cover layer 124 of the corresponding word line 120, thereby exposing the insulating cover layer 124 from the bottom of the through hole 101. In other words, a bottom surface of each through hole 101 is lower than the substrate 100, or a bottom surface of the isolating layer 130, so that, a bottom of a first insulating material layer 151 filling in each through hole 101 in the subsequent process will directly contact the insulating cover layer 124 of the corresponding word line 120, but not limited thereto.

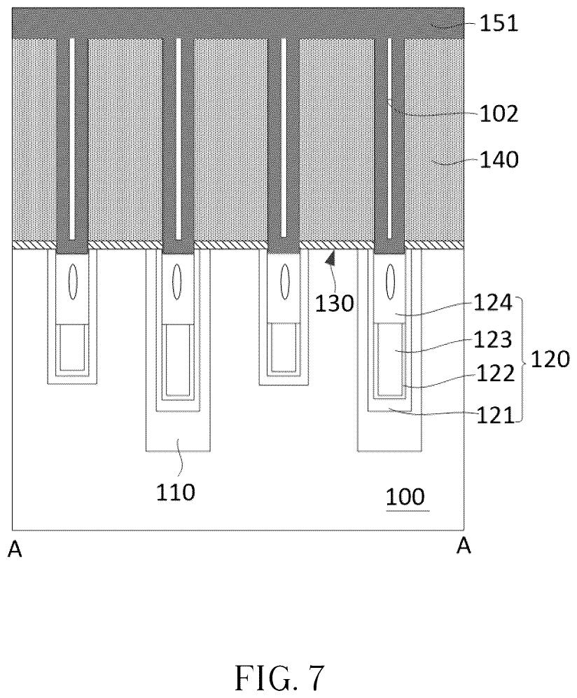

As shown in FIG. 7, the step S200 is carried out by first performing a deposition process such as chemical vapor deposition, to form a first insulating material layer 151 on the substrate 100, with the first insulating material layer 151 having a first seam 102 formed therein. At this time, the first insulating material layer 151 having a first seam 102 not only fills in each through hole 101, but also extends horizontally to cover the top surface of the sacrificial layer 140 exposed between the adjacent through holes 101. In one embodiment, the first insulating material layer 151 includes silicon oxide or silicon nitride, but is not limited thereto. The first seam 102 formed within the first insulating material layer 151 for example include a stripe-shaped slot in the vertical direction, and the length of a longer edge of the first seam 102 in the vertical direction is significantly larger than the length of a shorter edge of the first seam 102 in the horizontal direction. For example, the length of the longer edge of the first seam 102 may be N times larger than that of the shorter edge of the first seam 102, where N≥3. It is noted that, although FIG. 7 is exemplified by forming the first seam 102 within the first insulating material layer 151 filled in each through hole 101, the present invention is not limited thereto. In other embodiment, the first seam 102 may also be formed within the first insulating material layer 151 filled in a part of the through holes 101, that is, the first seam 102 is formed within the first insulating material layer 151 filled in at least one of the through holes 101, but not limited thereto.

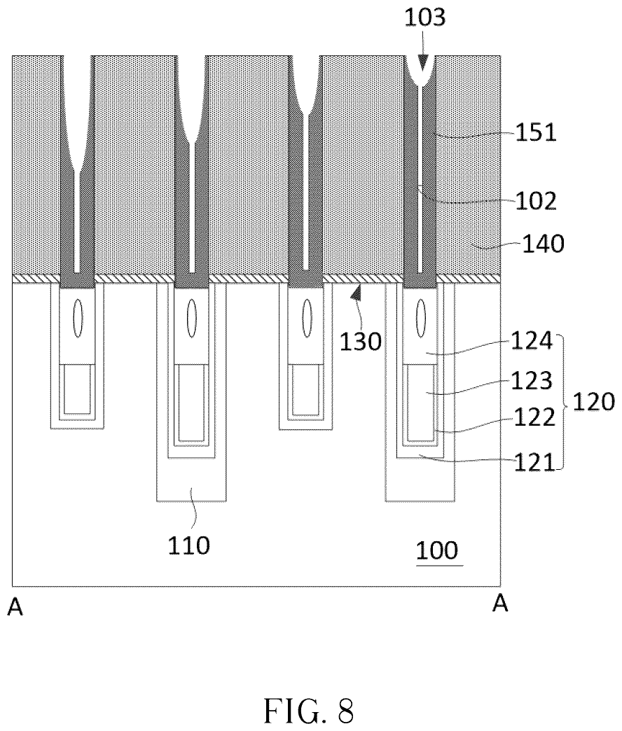

As shown in FIG. 8, performing an etching back process, such as a dry etching process, on the first insulating material layer 151 covering the top surface of the sacrificial layer 140, between the adjacent through holes 101, to remove the first insulating material layer 151 covering the top surface of the sacrificial layer 140, and to partially remove the first insulating material layer 151 filled in one or more of the through holes 101 at the same time. Then, the remaining first insulating material layer 151 forms the first insulating layer 151 having the first seam 102 as shown in FIG. 1, and the first insulating layer 151 has a recess 103 on the top thereof. In one embodiment, the bottom of the recess 103 directly contacts the first seam 102 within the first insulating layer 151 filled in the through hole 101. Also, the bottoms (namely, the lowest point) of the recesses 103 formed at the top of the first insulating layer 151 filled in different through holes 101 are at different heights, that is, the bottoms of the recesses 103 formed at the top of the first insulating layer 151 filled in different through holes 101 have a height difference in the vertical direction, therebetween, and the height difference may lead to shaped difference of the recesses 103, but not limited thereto.

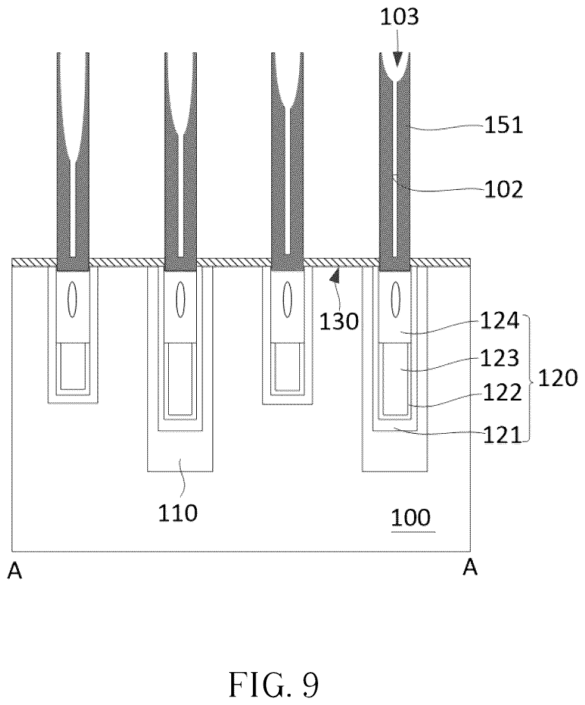

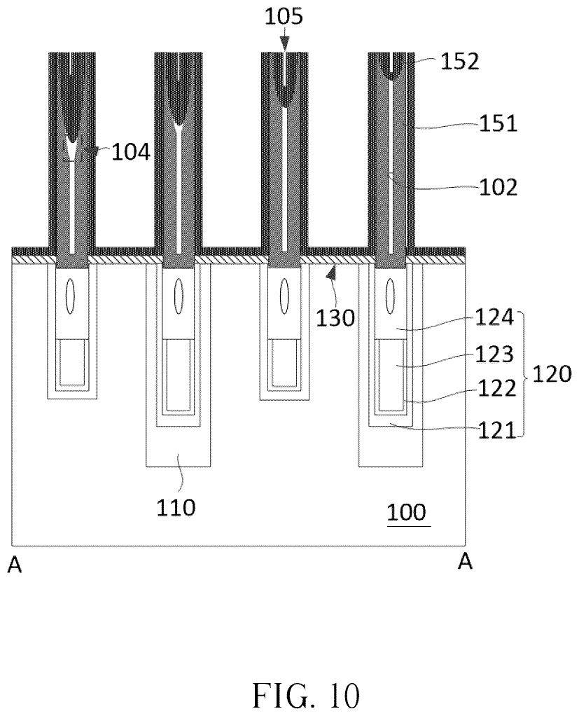

As shown in FIG. 9 and FIG. 10, the sacrificial layer 140 disposed between the adjacent through holes 101 is firstly removed, to expose two outer sidewalls of the first insulating layer 151, as shown in FIG. 9, and a third insulating layer 152 is next formed on the substrate 100, with the third insulating layer 152 filling in each recess 103 and covering the two outer sidewall of the first insulating layer 151. In one embodiment, due to various depths of the recesses 103, within the through holes 101 in the vertical direction, the third insulating layer 152 filling in the recesses 103 may generate a slot 105 within at least a part of the recesses 103, as shown in FIG. 10, or generate a gap 104 between the boundary between the third insulating layer 152 and the first insulating layer 151 filled in the same through hole 101, as shown in FIG. 10. The bottom surfaces of the slots 105 formed within the third insulating layer 152 filling in different recesses 103 may be optionally at the same level or at different levels, and also, the top surface and/or the bottom surface of the gap 104 between the third insulating layer 152 and the first insulating layer 151 filled in different through holes 101 may also be optionally at the same level or at different levels. In addition, the third insulating layer 152 and the first insulating layer 151 may both include an insulating material such as silicon oxide or silicon nitride, but not limited thereto, and the third insulating layer 152 and the first insulating layer 151 may include the same or different insulating materials, and preferably including different insulating materials.

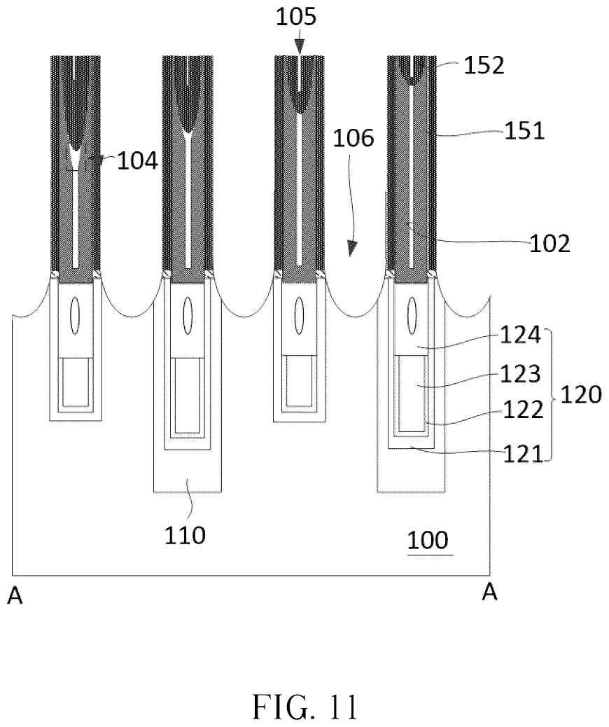

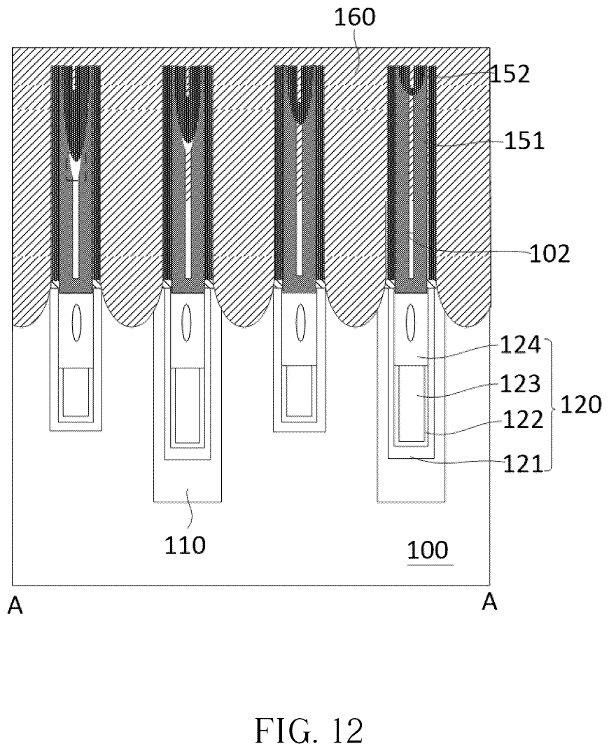

As shown in FIGS. 11 and 12, the step S300 is carried out by first performing an etching process such as dry etching process, to vertically remove the isolating layer 130 exposed form the third insulating layer 152 and the first insulating layer 151, as well as a portion of the substrate 100 underneath, to form a plurality of first contact openings 106 for forming a plurality of first contact structures 161 in the subsequent process. Then, a deposition process is performed, to form a first contact material layer 160 (for example including crystalline silicon or polysilicon) in the first contact openings 106, with the first contact material layer 160 not only filling in the first contact openings 106, but also horizontally overlaying the top surfaces and sidewalls of the first insulating layer 151 and the third insulating layer 152. That is, the first contact material layer 160 entirely covers the structures or films formed on the substrate 100.

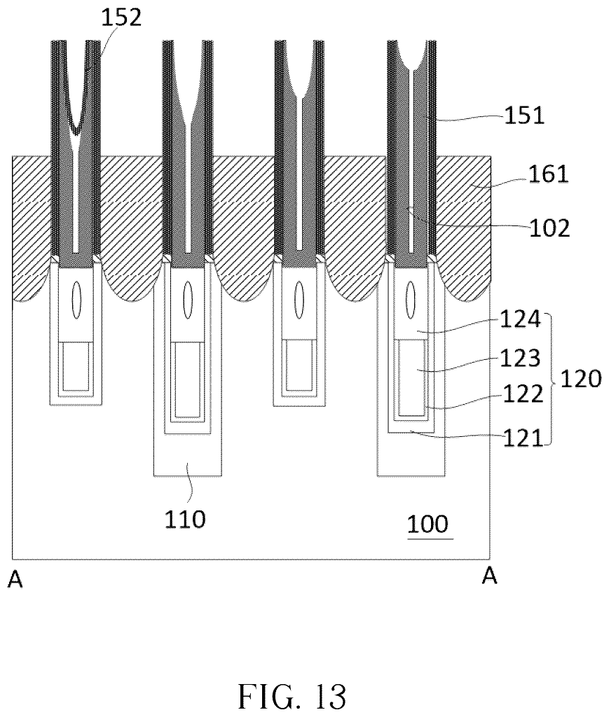

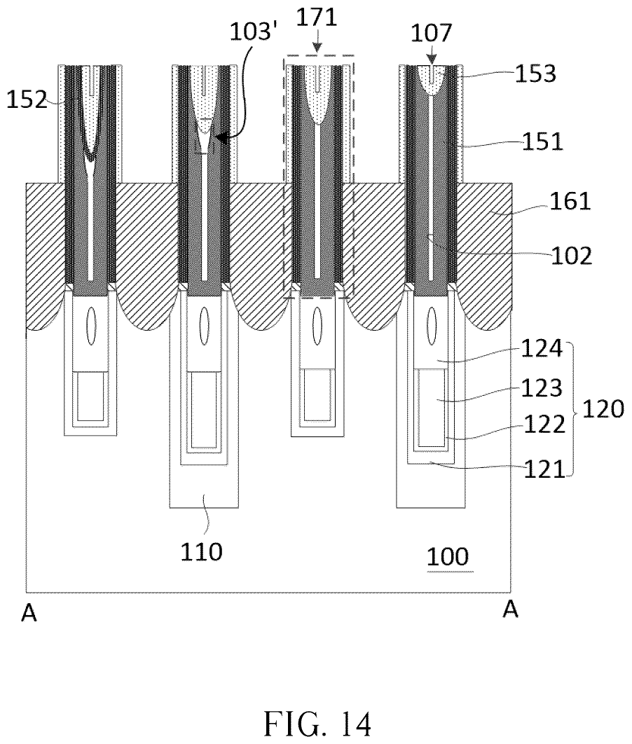

As shown in FIG. 13 and FIG. 14, an etching back process is performed to remove the first contact material layer 160 overlaying the first insulating layer 151 and the third insulating layer 152, to form the first contact structures 161 each having a top surface lower than the top surface of the first insulating layer 151 or the top surface of the third insulating layer 152. It is noted that, the third insulating layer 152 formed within the recesses 103 will also be partially remove or completely removed while etching back the first contact material layer 160. For example, the third insulating layer 152 formed within the recess 103 having a relative greater depth in the vertical direction will be partially remained after performing the etching back process, and the third insulating layer 152 formed within the recess 103 having a relative smaller depth in the vertical direction will be completely removed, but not limited thereto. Following these, a deposition process is performed, to form a second insulating layer 153 (for example including silicon nitride), with the second insulating layer 153 filling up the recess 103 and covering the two sidewalls of the third insulating layer 152, and with the second insulating layer 153 filled in the recess 103 having a seam 107 formed therein. Accordingly, the fabrications of the first insulating layer 151, the second insulating layer 153 and the third insulating layer 152 are accomplished, and the first insulating layer 151, the second insulating layer 153 and the third insulating layer 152 together form the first insulating structures 171.

It is noted that, due to various depths (namely the extending length in the vertical direction) between the recesses 103, the third insulating layer 152 formed within the recess 103 having a relative greater depth may generate a recess gap 103′ at the boundary between the first insulating layer 151 and the third insulating layer 152, as shown in FIG. 14, but not limited thereto.

Also, while forming the second insulating layer 153 having the second seam 107, the first seam 102 formed within the first insulating layer 151 of at least one of the first insulating structure 171 may be in communication with the second seam 107 formed within the second insulating layer 153 (as shown in FIG. 2), and/or, the first seam 102 formed within the first insulating layer 151 of at least one of the first insulating structure 171 may be in direct contact with the recess gap 103′ between the first insulating layer 151 and the second insulating layer 153, with the first seam 102, the recess gap 103′ and the seam 107 within the same first insulating structure 171 being communicated with each other.

After that, a deposition process and an etching process are performed, to form a silicide layer 162 on the top surface of each first contact structure 161, and a plurality of second contact structures 163 (for example including titanium nitride and/or tungsten) is formed on the silicide layer 162, being separately between the adjacent ones of the first insulating structures 171. Each of the second contact structures 163 further extends in the horizontal direction to partially overlay the top surface of a corresponding one of the first insulating structures 171. Next, a plurality of second insulating structures 172 (for example including silicon oxide or silicon nitride) are formed between the adjacent second contact structures 163, with the second insulating structures 172 each crossing through the second contact structures 163 to directly contact the corresponding first insulating structure 171. In one embodiment, a length of each second insulating structure 172 in the vertical direction may vary with processes, so that a part of the second insulating structures 172 will cross through the corresponding first insulating structures 171 in the vertical direction, to directly contact the recess gap 103′ within the corresponding first insulating structures 171. That is, the part of the second insulating structures 172 directly contacts the recess gap 103′ between the first insulating layers 151 and the second insulating layers 153 in the corresponding first insulating structures 171, as shown in FIG. 1 and FIG. 2. Alternately, another part of the second insulating structures 172 may also contact the gap 104 between the third insulating layer 152 and the first insulating layer 151 in the corresponding first insulating structures 171, or directly contact the second seam 107 within the second insulating layer 153 in the corresponding first insulating structures 171, but not limited thereto.

Then, a plurality of capacitors 180 is formed on the second contact structures 163. In one embodiment, each capacitor 180 may include a lower electrode 181, a capacitor dielectric layer 182 and an upper electrode 183. The lower electrode 181 and the upper electrode 183 for example includes a conductive material, with the lower electrode 181 for example including doped silicon, tungsten, copper, titanium nitride or other suitable material, and with the upper electrode 183 for example including titanium nitride, tantalum nitride, silicon germanium, a combination thereof or other suitable conductive materials, but not limited thereto. The capacitor dielectric layer 182 for example includes a high-k dielectric material like TaO₂, TaAlO, TaON, Al₂O₃, Al₂SiO₅, HfO₂, HfSiO, ZrO₂, ZrSiO₂, TiO₂, TiAlO₂, BST((Ba/Sr)TiO₃), STO(SrTiO₃), BTO(BaTiO₃), PZT(Pbₓ(Zr/Ti)₁₋ₓO₃), (Pb/La) (Zr/Ti)O₃, Ba(Zr/Ti)O₃, Sr(Zr/Ti)O₃, a combination thereof or other suitable materials.

Through these performances, the fabrication of the semiconductor device as shown in FIG. 1 or in FIG. 2 is accomplished. It is noted that the term “conformal” mentioned in the present invention refers to the morphological similarities and correlations between two or more shapes, to form a continuous structural shape.

In summary, according to the present invention, each of the first insulating structure at least includes a first insulating layer and a second insulating layer, with the first insulating layer and the second insulating layer of at least one first insulating structure respectively including a seam disposed therein, for example being a first seam disposed within the first insulating layer and a second seam disposed within the second insulating layer. Also, the first insulating layer and the second insulating layer of at least one first insulating structure further define a gap between the first insulating layer and the second insulating layer. Thus, through arranging the first insulating structure having a multilayer structure, and a plurality of insulating layer disposed therein having a seam and/or a gap, the semiconductor device of the present invention enables to gain better function and structural reliability

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first insulating structure, disposed on the substrate, the first insulating structure comprising a first insulating layer and a second insulating layer, wherein a first seam is disposed in the first insulating layer and a second seam is disposed in the second insulating layer; and
a first contact structure, disposed adjacent to the first insulating structure.

2. The semiconductor device according to claim 1, wherein the first insulating structure further comprises a recess gap between the first insulating layer and the second insulating layer thereof, wherein a maximum width of the recess gap in a horizontal direction is greater than a maximum width of the first seam within the first insulating layer in the horizontal direction.

3. The semiconductor device according to claim 2, wherein the recess gap directly contacts the first seam and/or the second seam.

4. The semiconductor device according to claim 2, wherein a top surface of the recess gap is higher than a top surface of the first contact structure.

5. The semiconductor device according to claim 1, further comprising:
a word line, disposed within the substrate, being overlaid by the first insulating structure in a vertical direction of the substrate.

6. The semiconductor device according to claim 1, the first insulating structure further comprising:
a third insulating layer, disposed between the first insulating layer and the second insulating layer.

7. The semiconductor device according to claim 6, wherein the first insulating structure comprises a gap between the third insulating layer and the first insulating layer, and the gap contacts the first seam.

8. The semiconductor device according to claim 1, wherein the first seam within the first insulating layer is overlaid by the second seam within the second insulating layer in vertical direction.

9. The semiconductor device according to claim 1, wherein the first seam within the first insulating layer is communicated with the second seam within the second insulating layer.

10. The semiconductor device according to claim 6, wherein the third insulating layer further disposed on two outer sidewalls of the first insulating layer.

11. The semiconductor device according to claim 10, wherein the second insulating layer extends to cover a partial sidewall of the third insulating layer disposed on the two outer sidewall of the first insulating layer.

12. The semiconductor device according to claim 7, further comprising:
a second contact structure, disposed on the first contact structure, wherein the second contact structure extends in a horizontal direction to cover a partial surface of the first insulating structure.

13. The semiconductor device according to claim 12, further comprising:
a second insulating structure, disposed adjacent to the second contact structures, wherein the second insulating structure directly contacts the recess gap of the first insulating structure.

14. The semiconductor device according to claim 12, further comprising:
a second insulating structure, disposed adjacent to the second contact structures, wherein the second insulating structure directly contacts the second seam within the second insulating layer of the first insulating structure.

15. A method of forming a semiconductor device, comprising:
providing a substrate;
forming an insulating structure, disposed on the substrate, the first insulating structure comprising a first insulating layer and a second insulating layer, wherein the first insulating structure comprises a first seam and in the first insulating layer and a second seam in the second insulating layer, respectively; and
forming a first contact structure adjacent to the first insulating structure.

16. The method of forming the semiconductor device according to claim 15, forming the first insulating structure, comprising:
forming a sacrificial layer on the substrate, the sacrificial layer comprising a through hole;
forming a first insulating material layer filled in the through hole, wherein the first seam is formed within the first insulating material layer;
performing an etching back process to partially remove the first insulating material layer, to form a recess on an upper portion thereof, wherein a bottom portion of the recess contacts the first seam; and
forming the second insulating layer filled in the recess and extended to partially overlay two sidewalls of the first insulating layer, wherein the second seam is formed within the second insulating layer.

17. The method of forming the semiconductor device according to claim 16, wherein the first insulating structure comprises a recess gap between the first insulating layer and the second insulating layer thereof, and a maximum width of the recess gap in a horizontal direction is greater than a maximum width of the first seam within the first insulating layer in the horizontal direction.

18. The method of forming the semiconductor device according to claim 16, before forming the second insulating layer, further comprising:
forming a third insulating layer between the first insulating layer and the second insulating layer, and the third insulating layer extends to cover two outer sidewalls of the first insulating layer.

19. The method of forming the semiconductor device according to claim 18, wherein the first insulating structure comprises a gap between the third insulating layer and the first insulating layer, and the gap contacts the first seam.
